(19) United States
(12) Patent Application Publication
(10) Pub. No.: US 2008/0296689 A1
(43) Pub. Date: Dec. 4, 2008

(54) Nanotube dual gate transistor and method of operating the same

(76) Inventors: Dawei Wang, Irvine, CA (US); Steffen McKernan, San Clemente, CA (US)

Correspondence Address: GREENBERG TRAURIG LLP (LA), 2450 COLORADO AVENUE, SUITE 400E, INTELLECTUAL PROPERTY DEPARTMENT, SANTA MONICA, CA, 90404, US

(21) Appl. No.: 12/128,812

(22) Filed: May 29, 2008

Related U.S. Application Data
(60) Provisional application No. 60/940,495, filed on May 29, 2007.

(51) Int. Cl. H01L 29/00

(52) U.S. Cl. 257/365; 257/E29.001

(57) ABSTRACT

A nanotube dual gate transistor and associated method of use are provided. The nanotube dual gate transistor includes a substrate, a nanotube material, a source conductor and a drain conductor, a top gate and a back gate. The nanotube material is formed over the substrate having a nanotube channel with a first end and a second end. The source conductor is coupled to the first end of the nanotube channel and the drain conductor is coupled to the second end of the nanotube channel. The back gate is formed under one or more of the devices for receiving a DC signal for establishing a desired optimal operational state of the device(s). The top gate is formed over the nanotube channel for receiving an AC signal for high frequency operation of the device(s) with low gate capacitance.

### RELATED APPLICATION

This application claims the benefit of and priority to U.S. Provisional Application Ser. No. 60/940,495, filed May 29, 2007, the contents of which are incorporated by reference herein in its entirety.

### BACKGROUND

This disclosure relates to nanotube (NT) field effect transistors (FETs), and more particularly to a nanotube dual gate transistor and associated method of use.

### SUMMARY

According to a feature of the disclosure, more effective control of transistor action vital to continuing improvements in electronics is provided by minimizing capacitance and optimizing control of NT FETs to increase their performance, improve their ease of use, and provide application flexibility.

In accordance with one or more embodiments, a nanotube dual gate transistor is provided along with a method for operating the same. The nanotube dual gate transistor includes a substrate, an insulating layer, a source conductor, a drain conductor, a nanotube material, a top gate and a back gate. The insulating layer is formed on the substrate. The nanotube material is formed on the insulating layer and having a channel with a first end and a second end. The source conductor and a drain conductor are formed on the insulating layer. The first end of the nanotube material is coupled to the source conductor while the second end of the nanotube material is coupled to the drain conductor. In one or more embodiments, a dielectric layer may be formed to cover portions of the nanotube material, the source conductor and the drain conductor. The top gate is formed on the dielectric layer and above a segment of the channel, such that the top gate extends across only a portion of the nanotube channel. In this manner, the dielectric layer isolates the top gate from the nanotube channel. Alternatively, the top gate can be isolated from the nanotube channel without the use of a dielectric layer by forming the top gate directly on the nanotube channel using a electrically dissimilar conductive material than the nanotube channel. The back gate is formed to comprise at least a region of the substrate. The back gate is activatable to establish a desired operational state for the nanotube dual gate transistor or several nanotube dual gate transistors in the region, while the top gate is used to operate the nanotube dual gate transistor based in combination with the operational state imparted by the back gate. By utilizing a top gate that only partially covers the nanotube channel, a low capacitance device is provided that can operate with high performance at high frequency while the back gate can be used to put the transistor in states optimized for high power, high efficiency, high linearity or other applications.

In one or more embodiments, rather than using a region of the substrate as the back gate, a metal layer can be formed between at least a region of the substrate and the nanotube material to serve as the back gate. In such embodiments, a first insulating layer is formed on the substrate and the metal layer is formed on insulating layer. A second insulating layer is formed on the metal layer. The nanotube material is then formed on the second insulating layer having a channel with a first end and a second end. The source conductor and a drain conductor are formed on the second insulating layer. The first end of the nanotube material is coupled to the source conductor while the second end of the nanotube material is coupled to the drain conductor. Either a dielectric layer is formed to cover portions of the nanotube material, the source conductor and the drain conductor with the top gate being formed on the dielectric layer above a segment extending across only a portion of the nanotube channel or the top gate is formed directly on the nanotube channel using a electrically dissimilar conductive material than the nanotube channel. The metal layer is then used as a back gate for at least a region of the substrate to put the nanotube dual gate transistor(s) in that region in states optimized for high power, high efficiency, high linearity or other applications while the top gate that only partially covers the nanotube channel provides a low capacitance control that can operate with high performance at high frequency.

In one or more embodiments, the semiconductor device includes a substrate, a nanotube material, a source conductor, a drain conductor, and a means for controlling the semiconductor device at high frequency operation with low gate capacitance. The semiconductor device may further include a means for optimizing an operational state of the semiconductor device.

In one embodiment, the method includes applying a DC signal to the back gate to establish a desired optimal operation state for the nanotube dual gate transistor, and applying an AC signal to the top gate to operate the nanotube dual gate transistor at high frequency with low gate capacitance.

### DRAWINGS

The above-mentioned features and objects of the present disclosure will become more apparent with reference to the following description taken in conjunction with the accompanying drawings wherein like reference numerals denote like elements and in which:

FIG. 1 illustrates a schematic drawing of a nanotube dual gate transistor in accordance with one embodiment of the present disclosure.

FIG. 2 illustrates a schematic drawing of a nanotube dual gate transistor in accordance with one embodiment of the present disclosure.

FIG. 3 illustrates an exemplary flow chart representing a method for operating the nanotube dual gate transistor of FIG. 1, according to one embodiment of the present disclosure.

### DETAILED DESCRIPTION

Embodiments described herein are directed to a method and device for providing dual gate transistor control using both a gate specific to a single transistor and a substrate back gate to achieve high performance.

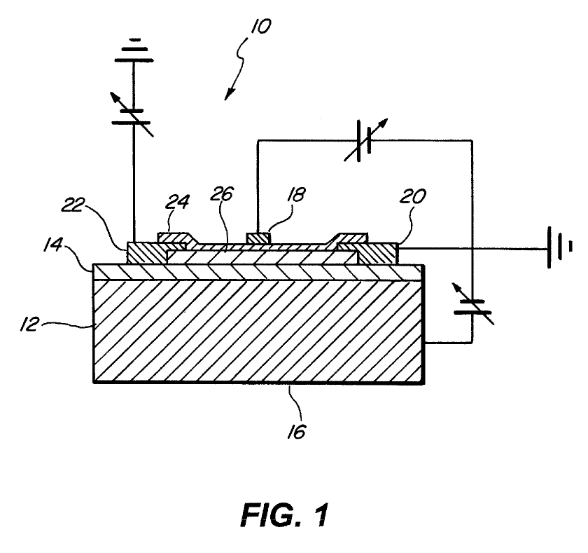

FIG. 1 illustrates a schematic drawing of a nanotube dual gate transistor 10 in accordance with one embodiment of the present disclosure. The nanotube dual gate transistor 10 may include a substrate 12, an insulating layer 14, a back gate 16, a top gate 18, a source 20, a drain 22, a dielectric layer 24 and a nanotube material 26. The substrate region 12 may be a silicon substrate. In one embodiment, the substrate 12 is a high resistivity silicon substrate. The insulating layer 14 is formed on the substrate 12. The nanotube material 26 is formed on the insulating layer 14 having a channel with a first end and a second end extending between a source 20 and a drain 22 formed on the insulating layer 14. The first end of the channel of nanotube material 26 is coupled to the source conductor 20 while the second end of the channel of nanotube material 26 is coupled to the drain conductor 22. The insulating region 14 may be used to isolate the substrate 12 from the nanotube material 26, the source 20 and the drain 22. In one embodiment, the insulating region 14 may be a silicon dioxide layer with a thickness of about 100 nm to about 300 nm.

To enhance control of the nanotube dual gate transistor 10 for high frequency response, the entire substrate 12 or an isolated region of the substrate 12 may be used as a back gate 16. In one embodiment, the nanotube dual gate transistor 10 may further be controlled by gating part of its channel using a top gate 18. In one or more embodiments, a dielectric layer 24 may be formed to cover portions of the nanotube material 26, the source conductor 20 and the drain conductor 22. The top gate 18 is formed on the dielectric layer 24 and above a segment of the nanotube channel, such that the top gate 18 extends across only a portion of the nanotube channel extending between the source conductor 20 and the drain conductor 22. In this manner, the dielectric layer 24 isolates the top gate 18 from the nanotube material 26. Alternatively, the top gate 18 can be isolated from the nanotube channel 26 without the use of dielectric layer 24 by forming the top gate 18 directly on the nanotube material 26 (not shown) using an electrically dissimilar conductive material than the nanotube material 26. The top gate 18 is formed above only a portion of the channel region of the nanotube material 26 in order to reduce gate capacitance. In one embodiment, the top gate 18 may be formed by deposition of gold on top of titanium. The gold may have a thickness of about 75 nm and the titanium may have a thickness of about 10 nm.

In one embodiment, the source 20 and the drain 22 may be made from one or more conductive materials, such as palladium and/or gold. For example, gold with a thickness of about 60 nm on top of palladium with a thickness of about 10 nm. The dielectric layer 24 may be made from an insulating material, such as silicon dioxide. In one or more embodiments, the dielectric layer 24 may possess a thickness of about 10 nm to about 100 nm. The nanotube material 26 extends from the source 20 to the drain 22. In one embodiment, the nanotube material 26 is a cylindrical carbon nanotube with a diameter of about 1 nm to about 2 nm. As can be envisioned by a person skilled in the art, a plurality of nanotube materials 26 may be used to extend from the source 20 to the drain 22.

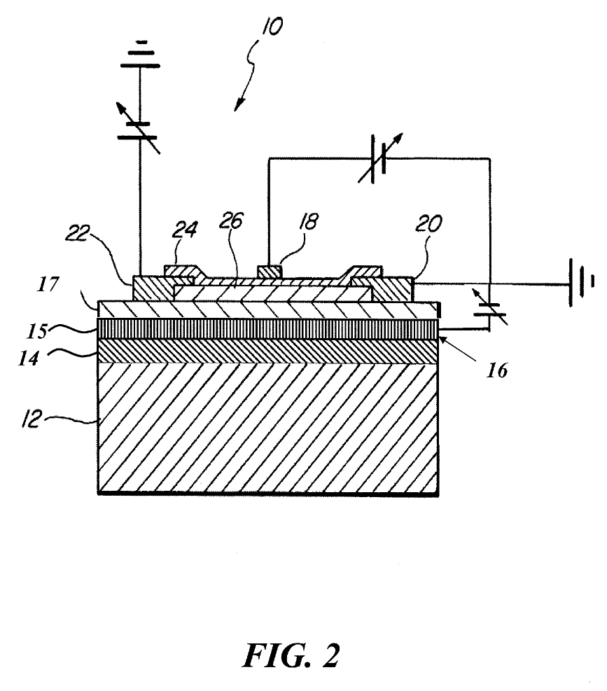

In one or more embodiments, rather than using a region of the substrate 12 as the back gate 16, a metal layer 15 can be formed between at least a region of the substrate 12 and the nanotube material 26 to serve as the back gate 16, as illustrated in FIG. 2. In such embodiments, a first insulating layer 14 is formed on the substrate 12 and the metal layer 15 is formed on insulating layer 14. A second insulating layer 17 is formed on the metal layer 15. The nanotube material 26 is then formed on the second insulating layer 17 having a channel with a first end and a second end. The source conductor 20 and a drain conductor 22 are formed on the second insulating layer 17. The first end of the channel of nanotube material 26 is coupled to the source conductor 20 while the second end of the channel of nanotube material 26 is coupled to the drain conductor 22. Either a dielectric layer 24 is formed to cover portions of the nanotube material 26, the source conductor 20 and the drain conductor 22 with the top gate 18 being formed on the dielectric layer 24 above a segment extending across only a portion of the nanotube channel 26 or the top gate 18 is formed directly on the nanotube channel 26 using a electrically dissimilar conductive material than the nanotube channel 26. The metal layer 15 is then used as a back gate for at least a region of the device 10 to put the nanotube dual gate transistor(s) 10 in that region in states optimized for high power, high efficiency, high linearity or other applications while the top gate 18 that only partially covers the nanotube channel 26 provides a low capacitance control that can operate with high performance at high frequency.

In operation of the nanotube dual gate transistor 10 in accordance with one or more embodiments, the back gate 16 is activatable to establish a desired operational state for the nanotube dual gate transistor 10 or several nanotube dual gate transistors 10 in the region of the substrate 12 corresponding to back gate 16. The top gate 18 is then used to operate the nanotube dual gate transistor 10 based in combination with the operational state imparted by the back gate 16. By utilizing a top gate 18 that only partially covers the nanotube channel, a low capacitance device is provided that can operate with high performance at high frequency while the back gate 16 can be used to put the nanotube dual gate transistor 10 in states optimized for high power, high efficiency, high linearity or other applications.

In one or more embodiments, a plurality of nanotube dual gate transistors 10 are formed on the substrate 12, such that each nanotube dual gate transistor 10 is formed in accordance with one or embodiments described herein. A common back gate 16 is formed under the nanotube channel 26 in each of the plurality of nanotube dual gate transistors 10, such as by using a region of the substrate 12 or a region of metal layer 15 that extends under the nanotube channels 26 in a plurality of nanotube dual gate transistors 10 as a common back gate 16 that is activatable for establishing a desired operational state for each of the plurality of nanotube dual gate transistors 16. Each of the plurality of nanotube dual gate transistors 10 include their own respective top gate 18 that is separately activatable for separately controlling each of the plurality of nanotube dual gate transistors 10 at high frequency operation with low gate capacitance.

In one or more embodiments, a DC signal may be applied to the back gate 16 to regulate and/or control the nanotube dual gate transistor 10 to a desired optimal state, such as, for example, maximum power or signal linearity. Using different biases on the back gate 16 will cause the nanotube dual gate transistor 10 to exhibit different characteristics. For example, a DC signal may be applied to the back gate 16 to cause the ON or OFF switching of the nanotube dual gate transistor 10. An AC signal may be applied to the top gate 18 to drive the nanotube dual gate transistor 10 at high frequency for signal amplification.

In one embodiment, dual gate transistor control is provided using both a top gate 18 specific to a single transistor and a substrate back gate 16 to achieve high performance. More effective control of transistor action is vital to continuing improvements in electronics. Nanotubes and in particular carbon nanotubes (CNTs) can be used to make high performance FETs which can operate from DC to gigahertz or higher frequencies. As can be appreciated by a person skilled in the art, the nanotube dual gate transistor 10 controls capacitance and optimizes control of transistors to increase their performance, and improve their ease of use and application flexibility.

The nanotube dual gate transistor 10 provides reduced gate capacitance and optimized transistor operation for ease of use. By reducing the gate capacitance, performance of the nanotube dual gate transistor 10 improves. In one embodiment, the nanotube dual gate transistor 10 may use the back gate 16 to turn the transistor 10 ‘on’ and then use a small top gate voltage to turn the gated region ‘off,’ thereby minimizing capacitance and improving the performance of the transistor 10 as a transistor ‘switch.’

For optimization and ease of use, the back gate 16 may be used to put the transistors in the optimal region of operation for a given application with the transistor 10, which may be controlled by using a smaller voltage on the top gate 18. More broadly, the back gate 16 may be used to put the transistor 10 into a region where small changes to the top gate voltage produce a desired change in the transistor 10, such as maximum or minimum changes to the drain-source current at a given voltage across the drain-source contacts 20 and 22. Hence, the nanotube dual gate transistor 10 not only reduces gate capacitance but also allows the transistor 10 to be controlled by smaller voltage changes to the top gate 18 than the changes required by a single gate. Using a large back gate voltage may also facilitate the use of the back gate 16 to create either ‘n’ or ‘p’ type behavior as appropriate for a given application.

The nanotube dual gate transistor 10 can implemented in any number of different types of transistors, including analog transistors and digital applications which often run at GHz speeds where minimizing capacitance and voltages required for switching is also important. Communication devices are but one application of analog transistors that are well-suited for the nanotube dual gate transistor 10.

As can be appreciated by a person skilled in the art, the nanotube dual gate transistor 10 allows high performance NT devices to be achieved. By using a back gate 16 to fully turn on the NT channel, a partially covered local gate 18 can be used to efficiently control each individual NT FET. As such, low capacitance for high performance can be achieved.

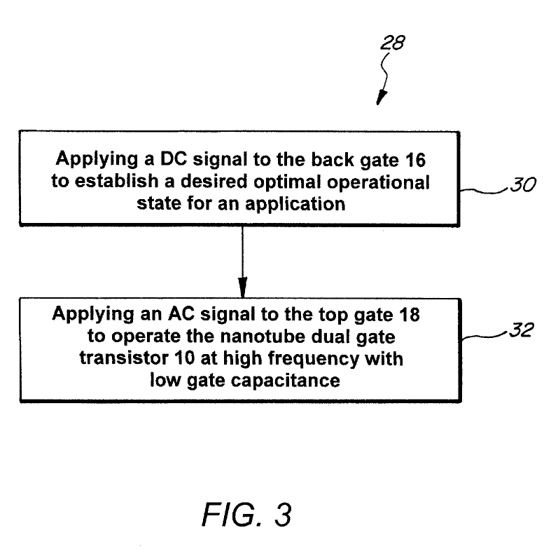

FIG. 3 illustrates an exemplary flow chart 28 representing a method for operating the nanotube dual gate transistor 10 of FIG. 1, according to one embodiment of the present disclosure. In one embodiment, the nanotube dual gate transistor 10 operates by applying a DC signal to the back gate 16 to establish a desired optimal operation state for a certain application (30). For example, if the nanotube dual gate transistor 10 is used as a transistor switch, the DC signal is applied to the back gate 16 to control the desired operation. In one embodiment, an AC signal may be applied to the top gate 18 to operate the nanotube dual gate transistor 10 at high frequency with low gate capacitance (32).

While the nanotube dual gate transistor 10 and related method of use have been described in terms of what are presently considered to be the most practical and preferred embodiments, it is to be understood that the disclosure need not be limited to the disclosed embodiments. It should also be understood that a variety of changes may be made without departing from the essence of the invention. Such changes are also implicitly included in the description. They still fall within the scope of this invention. It should be understood that this disclosure is intended to yield a patent covering numerous aspects of the invention both independently and as an overall system and in both method and apparatus modes.

Further, each of the various elements of the invention and claims may also be achieved in a variety of manners. This disclosure should be understood to encompass each such variation, be it a variation of an embodiment of any apparatus embodiment, a method or process embodiment, or even merely a variation of any element of these. Particularly, it should be understood that as the disclosure relates to elements of the invention, the words for each element may be expressed by equivalent apparatus terms or method terms—even if only the function or result is the same. Such equivalent, broader, or even more generic terms should be considered to be encompassed in the description of each element or action. Such terms can be substituted where desired to make explicit the implicitly broad coverage to which this invention is entitled.

It should be understood that all actions may be expressed as a means for taking that action or as an element which causes that action. Similarly, each physical element disclosed should be understood to encompass a disclosure of the action which that physical element facilitates.

It should be understood that various modifications and similar arrangements are included within the spirit and scope of the claims, the scope of which should be accorded the broadest interpretation so as to encompass all such modifications and similar structures. The present disclosure includes any and all embodiments of the following claims.

1. A semiconductor device, comprising:
a substrate;
a source conductor and a drain conductor formed over the substrate;
a nanotube material formed over the substrate having a nanotube channel with a length extending between a first end and a second end, wherein the first end is coupled to the source conductor and the second end is coupled to the drain conductor;
a back gate formed under the nanotube channel and activatable to establish a desired operational state of the semiconductor device; and
a top gate formed over a portion of the nanotube channel such that the top gate extends across a length that is less than the length of the nanotube channel, the top gate being activatable to operate the semiconductor device in combination with the operational state established by the back gate.

2. The semiconductor device of claim 1, further comprising a dielectric layer formed between the top gate and the nanotube material to isolate the top gate from nanotube material.

3. The semiconductor device of claim 1, wherein the top gate and the nanotube material comprise electrically dissimilar materials to isolate the top gate from nanotube material.

4. The semiconductor device of claim 1, further comprising an insulating layer formed between the substrate and the source conductor, the drain conductor and the nanotube material.

5. The semiconductor device of claim 1, wherein the nanotube coverage by the top gate is significantly smaller than the nanotube channel.

6. The semiconductor device of claim 1, further comprising a DC power source connected to the back gate for applying a DC signal to the back gate to turn ON the semiconductor device.

7. The semiconductor device of claim 1, wherein the source conductor and the drain conductor comprise a low resistance metallic material selected from a group consisting of palladium and gold.

8. The semiconductor device of claim 1, wherein the top gate comprises a metal selected from a group consisting of titanium and gold.

9. The semiconductor device of claim 1, wherein the top gate is activatable to operate at high frequency with low gate capacitance.

10. The semiconductor device of claim 1, wherein the at least a portion of the substrate is formed to be the back gate.

11. The semiconductor device of claim 1, wherein the back gate comprises a metal layer formed between at least a region of the substrate and the nanotube material.

12. A nanotube dual gate transistor, comprising:
a substrate;
a source conductor and a drain conductor formed over the substrate;
a nanotube material formed over the substrate having a nanotube channel with a length extending between a first end and a second end, wherein the first end is coupled to the source conductor and the second end is coupled to the drain conductor;
a back gate formed under the nanotube channel and arranged for receiving a DC signal for establishing a desired operational state for the semiconductor device; and
a top gate formed over a portion of the nanotube channel and arranged for receiving an AC signal for high frequency operation of the semiconductor device with low gate capacitance.

13. The semiconductor device of claim 12, wherein the top gate extends across a length that is substantially less than the length of the nanotube channel.

14. The nanotube dual gate transistor of claim 12, wherein the DC signal is applied to the back gate to turn ON the semiconductor device.

15. A semiconductor device, comprising:
a plurality of nanotube dual gate transistors formed on a substrate, each nanotube dual gate transistor including a semiconducting nanotube channel extending between a source conductor and a drain conductor and a top gate formed over the nanotube channel;
a common back gate formed under the nanotube channel in each of the plurality of nanotube dual gate transistors that is activatable for establishing a desired operational state for each of the plurality of nanotube dual gate transistors wherein the top gate in each of the plurality of nanotube dual gate transistors is separately activatable for separately controlling each of the plurality of nanotube dual gate transistors at high frequency operation with low gate capacitance.

16. The semiconductor device of claim 15, wherein the top gate in each of the plurality of nanotube dual gate transistors is formed over a portion of a respective nanotube channel such that the top gate extends across a length that is less than a length of the nanotube channel, the top gate being activatable to operate the semiconductor device in combination with the operational state established by the back gate.

17. The semiconductor device of claim 15, wherein at least a portion of the substrate is formed to be the common back gate.

18. The semiconductor device of claim 15, wherein the common back gate comprises a metal layer formed between at least a region of the substrate and the nanotube channels in the plurality of nanotube dual gate transistors.

19. The semiconductor device of claim 15, further comprising a DC power source connected to the back gate for applying a DC signal to the back gate to turn ON the plurality of nanotube dual gate transistors.

20. The semiconductor device of claim 19, further comprising an AC signal source coupled to the gates of the nanotube dual gate transistors for receiving an AC signal for high frequency gate transistors.

21. A method gate transistor having a top gate and a back gate, the method comprising:
applying a DC signal to the back gate to establish a desired optimal operation
applying an AC signal to the to operate the nanotube dual gate transistor at high frequency with low gate capacitance.
